(19) United States
(12) Patent Application Publication
(10) Pub. No.: US 2016/0340770 A1
(43) Pub. Date: Nov. 24, 2016

(54) High Magnetic Field Assisted Pulsed Laser Deposition System

(71) Applicant: Hefei Institutes of Physical Science of Chinese Academy of Sciences, Hefei City, Anhui (CN)

(72) Inventors: Jianming DAI, Hefei City, Anhui (CN); Kejun ZHANG, Hefei City, Anhui (CN); Qinzhuang LIU, Hefei City, Anhui (CN); Zhigao SHENG, Hefei City, Anhui (CN); Xuebin ZHU, Hefei City, Anhui (CN); Wenbin WU, Hefei City, Anhui (CN); Yuping SUN, Hefei City, Anhui (CN)

(73) Assignee: Hefei Institutes of Physical Science of Chinese Academy of Sciences, Hefei City, Anhui (CN)

(21) Appl. No.: 14/890,965

(22) PCT Filed: May 9, 2014
(86) PCT No.: PCT/CN2014/077154

§ 371 Date: Aug. 9, 2016

(30) Foreign Application Priority Data
Jan. 23, 2014 (CN) 201410033519.X

(51) Int. Cl. C23C 14/28; C23C 14/58

(52) U.S. Cl. CPC C23C 14/28; C23C 14/5806

(57) ABSTRACT

A type of High Magnetic Field Assisted PLD System consisting of pulsed laser and PLD cylindrical vacuum chamber inclusive of double-layer clip-sheath cylindrical chamber with water cooling located in the bore hole of superconducting magnet is disclosed. A flange plate in one side of the double-layer clip sheath is equipped with substrate heating table or laser heating table and rotating mechanism; the flange plate in another side is equipped with target components and moving/rotating mechanism. Either the substrate heating table or laser heating table is located in the center area of magnetic field of the superconducting magnet. A PLD (pulsed laser deposition) cylindrical vacuum chamber is located in the slide rail. A sealed laser leading-in chamber and a vacuum-sealed video-unit leading-in chamber is installed on the flange plate in one side of double-layer clip sheath cylindrical chamber.

This application is a national phase application of PCT/CN2014/007154 entitled “High Magnetic Field Assisted Pulse Laser Deposition System,” filed on May 9, 2014, which claims priority to Chinese patent application No. 201410033519.X entitled “high Magnetic Field Assisted PLD System,” filed on Jan. 23, 2014. The contents of the foregoing applications are incorporated herein by reference.

### FIELD OF THE INVENTION

The field relates to thin-film material preparation technology and a particular type of High Magnetic Field Assisted (PLD) Pulse laser depositions system.

### BACKGROUND OF THE INVENTION

At present, as an ideal and non-contacting outfield driving force, the magnetic field may improve activity of reactant, promote ionic diffusion and influence grain nucleation, growth, grain boundary migration and recrystallization, and even the magnetic field may change the electron spin and nuclear spin state of reactant, in order to induce, new chemical reaction process change preferential growth mode of materials and acquire materials with novel structure and physical property. During the process of material preparation, the magnetic field effect is directly related to additional magnetic field strength and material magnetic susceptibility. Therefore, non-magnetic (weak-magnetic) materials will take effect in a higher magnetic field.

The existing technology often combines the magnet and heat treatment devices to prepare materials in high magnetic field. For example, China Patent (Disclosure Number: CN2879162) discloses a kind of high-temperature thermal treatment device in higher magnetic field. The device may be used in metallurgical and physicochemical reactions, purification and refinement, etc., during material melting process, and to obtain fused solution with higher purity. In addition, it may be engaged in one-way-solidification of materials in high magnetic field and preparing directional and homogeneous materials. Recently, the devices and methods for thin-film deposition with thermal evaporation in laser heating evaporation in high magnetic field have been reported (Masahiro Tahashi, et al., Materials Transactions, Vol. 44, No. 2 (2003) pp. 285-289); another reported the research on thin-film growth by introducing weak magnetic field into PLD (Grigorenko A N, et al., Appl. Phys. Lett. 72 (26), (1998) 3445-3457).

The magnetic field is a permanent magnet installed on substrate table with simple structure. The magnet provides a fixed magnetic field with weak strength (1 t) and is not suitable for high temperature. China Patent (disclosure number: CN 101003890) reported a PLD (pulsed laser deposition) method to prepare thin film in magnetic field generated from ordinary electromagnets.

Similarly, as reported, a pair of permanent magnets is installed between target of

PLD vacuum chamber and substrate table (M. Shahid Rafique, et al., Thin Solid Films 545 (2013) 608-613) for thin-film growth in magnetic field. However, one using the foregoing method cannot change the strength because of weak strength and limitations by a transverse magnetic field. Nevertheless, from the perspective of material growth kinetics, the in-situ growth in magnetic field will produce more obvious effect than post-annealing treatment. As reported, a superconducting coil is set in ordinary PLD vacuum chamber (Jung Min Park, et al., Japanese Journal of Applied Physics 50 (2011) 09NB03) for thin-film in-situ growth in applied magnetic field and improving growth rate. The device utilizes a high-temperature superconducting coil to produce magnetic field with complex structure. Superconducting coil should work in liquid nitrogen temperature area, which may only provide 0-0.4 t magnetic field strength.

The previous China Patent (disclosure number: CN102877032A) for the applicant discloses a kind of PLD thin-film preparation system in high magnetic field. A superconducting magnet with higher room temperature and aperture is used to design a kind of special PDL vacuum chamber. The laser is transmitted to target from the projected quartz window in vacuum chamber to achieve thin-film deposition in high magnetic field. The structure makes rigorous requirements for the proportional relation (length:aperture) between the length of bore hole in superconducting magnet (or distance from magnetic field center to port) and aperture, namely, the length should be shorter and the aperture should be larger as much as possible. The proportion is 1:1 generally. The design difficulty and manufacturing cost of superconducting magnet in high magnetic field will be greatly improved because the system requires the uniformity of magnetic field distribution. If a chamber mirror is used, the mirror is easily polluted within the chamber, thus the energy of reflected light will be attenuated rapidly. Under high laser irradiation the polluted mirror is easily damaged, thus the design is unable to keep stable and work normally. In addition, due to fixed substrate heating table, the angle between heating table (substrate surface) and magnetic field cannot be changed, so it is unable to regulate the microstructure of thin-film growth in different magnetic fields. There remains a need for improved high magnetic field assisted pulse laser deposition systems.

### SUMMARY OF THE INVENTION

The invention is designed to provide a type of High Magnetic Field Assisted PLD System featuring stability and strong practicability.

The objective is achieved through the following technical plan:

High Magnetic Field Assisted PLD System consists of puled laser and PLD cylindrical vacuum chamber inclusive of double-layer clip sheath cylindrical chamber with water cooling located in the bore hole of superconducting magnet;

A flange plate in one side of the double-layer clip sheath is equipped with substrate heating table or laser heating table and rotating mechanism; the flange plate in another side is equipped with target components and moving/rotating mechanism. Either the substrate heating table or laser heating table is located in the center area of magnetic field of the superconducting magnet;

The PLD cylindrical vacuum chamber is placed horizontally, which is fixed to different sliding blocks using three groups of holder. The first and second sliding group 2 guide rail. Two groups of guide rail are fixed to an optical table;

The flange plate in one side of the double-layer clip sheath is equipped with substrate heating table or laser heating table and rotating mechanism is also equipped with sealed laser leading-in chamber and vacuum-sealed video-unit leading-in chamber;

The laser leading-in chamber is composed of incoming-light quartz glass window, emergent-light quartz glass window and anti-intense laser mirror. The pulsed laser should align with the incoming-light quartz glass window.

As shown in the above-mentioned technical plan, the invention provides High Magnetic Field Assisted PLD System. A type of high magnetic field assisted PLD growth system may be achieved if the high magnetic field is introduced in-situ during the preparation of PLD thin film. Because of the design of combined assembly (sealed laser leading-in chamber and slide rail), vacuum-sealed video leading-in chamber and rotatable laser heating substrate table, etc., the advantages of the system compromises low manufacturing cost, rational structure, simple assemble and operation, stable and reliable service, etc. The system may be used in PLD thin-film in-situ growth and post-annealing thermal treatment, and to regulate the material microstructure and physical property. The invention plays an important role in material science, condensed matter physics research and new material exploration.

As for the invention, a raised vacuum chamber is stretched into the electromagnetic field and higher magnetic field strength cannot achieve limitations by vacuum chamber and electromagnetic space. Because the field direction is vertical to the transmitting direction of excited plasma (transverse magnetic field), the charged particles will deviate from original transmitting direction under the effect of Lorentz Force and go against thin-film growth. Therefore, the device may be used in post-annealing treatment in downfield after thin-film deposition rather than thin-film in-situ growth in magnetic field.

### BRIEF DESCRIPTION OF THE DRAWINGS

Further features and advantages of the invention will become apparent from reading the following detailed description in conjunction with the following drawings, in which like reference numbers refer to like parts:

FIG. 1 (example 1) is the structure diagram of High Magnetic Field Assisted PLD System;

FIG. 2 (example 2) is the structure diagram of laser heating table in High Magnetic Field Assisted PLD System;

FIG. 3 (example 3) is the local structure diagram of High Magnetic Field Assisted PLD System.

### DETAILED DESCRIPTION

The examples and the referenced drawings in this detailed description are merely exemplary, and should not be used to limit the scope of the claims in any claim construction or interpretation.

### Modes to Implement the Invention

The optimum implement mode of High Magnetic Field Assisted PLD System:

The system consists of pulsed laser and PLD cylindrical vacuum chamber inclusive of double-layer clip sheath cylindrical chamber with water cooling located in the bore hole of superconducting magnet

With regard to double-layer clip sheath cylindrical chamber, the flange plate in one side is equipped with target components and moving/rotating mechanism. The substrate heating table and laser heating table are located in the center of superconducting magnet;

The PLD cylindrical vacuum chamber is placed horizontally, which is fixed to different sliding blocks using three groups of holder. The first and second sliding blocks are installed on group 1 guide rail; the third sliding block is installed on group 2 guide rail. Two groups of guide rail are fixed to an optical table;

A sealed laser leading-in chamber and a vacuum-sealed video-unit leading-in chamber is installed on the flange plate in one side of double-layer clip sheath cylindrical chamber equipped with substrate heating table or laser heating table and rotating mechanism;

The laser leading-in chamber is composed of incoming-light quartz glass window, emergent-light quartz glass window and anti-intense laser mirror. The pulsed laser should align with the incoming-light quartz glass window.

The laser leading-in chamber is composed of incoming-light quartz glass window, emergent-light quartz glass window and anti-intense laser mirror. The pulsed laser should align with the incoming-light quartz glass window.

The laser leading-in chamber is installed on the flange plate using a vacuum seal ring, which may adjust by moving forwards and backwards, and rotate.

Focusing lens is installed near to incoming-light quartz glass window, which is located in inside or outside of laser leading-in chamber;

In one example, the reflection angle of anti-intense laser mirror is a 45°-65° mirror.

The collimation laser uses several miliwatt low-power and continuous visible lasers (mW).

The target components include a target table with several target positions. Each target position is equipped with target materials. The target table is connected with moving/rotating mechanism inclusive of stepping motor. The stepping motor is connected with the target table through metal corrugated pipe.

The substrate heating table is equipped with heater inclusive of a spiral structure of double winding resistance wire. The outside of spiral structure is covered with heat shield. The rotating mechanism of substrate heating table contains a stepping motor.

The laser heating table is equipped with laser heating device inclusive of infrared high-power laser, fiver with metal sheath, vacuum sealed joints fixed in flange plate in one side and high temperature resistant fiber within double-layer clip sheath cylindrical chamber connected in turn. The fiver port of high temperature resistance fiber aligns with the heating table using a focusing lens.

The laser heating table uses sealed and cylindrical structure. The rotating mechanism of laser heating table contains stepping motor which is connected with laser heating table using a metal corrugated pipe and a transfer bar. The laser heating table is installed on the rotation axis.

The room temperature aperture of superconducting magnet is larger than or equal to φ100 mm. The maximum magnetic field strength is larger than or equal to 3 Tesla. PLD cylindrical vacuum chamber and materials of internal and external connectors apply non-magnetic or weak-magnetic materials.

The non-magnetic or weak-magnetic materials contain high-quality 304 stainless steel, 3161N stainless steel, high-purity oxygen-free copper and aluminum alloy materials.

Because the invention introduces high magnetic field in-situ during the process of preparing PLD thin-film, a type of high magnetic field assisted PLD thin-film growth system may be achieved. For the design of combined assembly (sealed laser leading-in chamber and slide rail), vacuum-sealed video leading-in chamber, collimation laser device and rotatable laser heating substrate table, etc., the advantage of the system comprises low manufacturing cost, rational structure, simple assembly and operation, stable and reliable service, etc. The system may be used in PLD thin-film in-situ growth and post-annealing thermal treatment, and to regulate the material microstructure and physical property. The invention plays and important role in material science, condensed matter physics research and new material exploration.

### Specific Embodiment 1

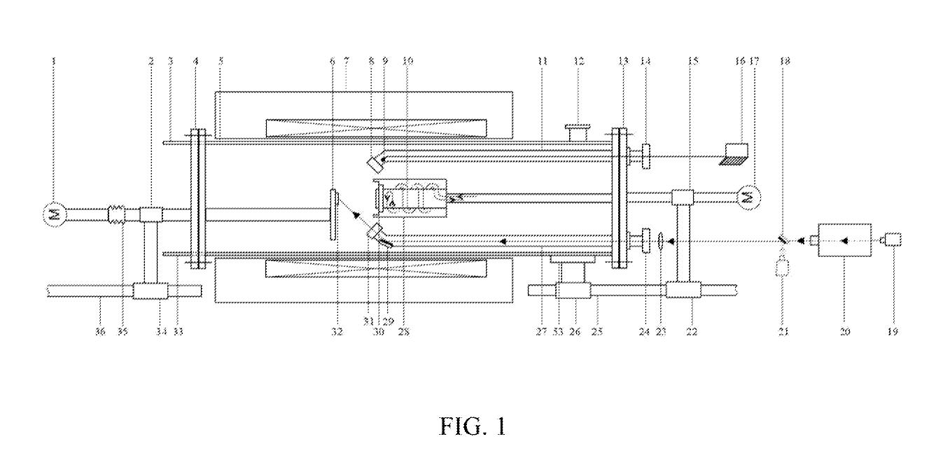

As shown in FIG. 1, the system is composed of superconducting magnet 7, pulsed laser 20, PLD cylindrical vacuum chamber, high vacuum unit (not shown), gas flow connected by vacuum seal with flange plate on both ends. It is composed of three parts:

double-layer clip-sheath cylindrical chamber used as water cooling 5, flange plate of heating table with substrate and rotating mechanism 13, and flange plate with target components and moving/rotating mechanism 4. The three parts are respectively fixed on sliding block 26, 22, and 34 used as water cooling 5, flange plate of heating table with substrate and rotating mechanism 4. The three parts are respectively fixed on sliding block 26, 22 and 34 using holder 53, 15, and 2. Sliding block 26 and 22 are installed on guide rail 25 and sliding block 24 is installed on guide rail 36. Two groups of guide rail are installed on optical table (not shown). The three parts may move one-dimensionally on the guide rail, which may be dismantled, assembled and operated easily. Double-layer clip-sheath cylindrical chamber 5 is equipped with water inlet 33 and water outlet 3, which may connect circulating water cooling system not shown) and cool the chamber. Double-layer clip-sheath cylindrical chamber 5 is located in the bore hole of superconducting magnet 7. The flange plate of heating table with substrate rotating mechanism 13 is equipped with sealed laser leading-in chamber 27 and vacuum-sealed video-unit leading-in chamber 11. The sealed laser leading-in chamber 27 consists of incoming-light quartz glass window 24, emergent-light quartz glass window 31 and anti-intense laser mirror 29 with special angle design. The sealed laser leading-in chamber 27 id installed on the flange plate 13 with vacuum seal ring, which may adjust by moving forwards and backwards, and rotating. Focusing lens 23 (focal length: 700 mm) is placed near to incoming-light quartz glass window 24 outside the vacuum chamber. The special reflection angle (laser incident angle) of anti-intense laser mirror 29 is at an angle of 65° according to the internal space of cylindrical vacuum room and the distribution position of various parts. Vacuum-sealed video-unit leading-in chamber 11 is equipped with quartz glass window 8. Optical camera device 9 extends into the chamber from entrance 14 of video-unit leading-in chamber 11 and shoots the target position of target table 6 and laser alignment from quartz glass window 8. Optical images are observed and recorded by CCD (charge-coupled device) acquisition signal connecting with computer 16. In order to observe and adjust whether pulsed laser aligns with target material 32, a collimation laser 19 is set in the laser light path. The laser emitted by collimation laser 19 is coaxial (coincided) with the laser light path emitted by pulsed laser 20. Collimation laser 19 applies the continuous visible laser with 3 mW output power and 635 nm wavelength. The direction of arrow on laser light path in the figure indicates the transmission direction of laser. It is necessary to open collimation laser and video system when adjusting the light patch. The high-energy pulsed laser may align completely after aligning the collimation laser.

The target table 6 on flange plate 4 with target components and moving/rotating mechanism has three target positions. Each target position is equipped with target material 32 φ20 mm). A shield cover (not shown) is installed in front of target table 6. Upon using a coating film, a target position may be exposed for pulsed laser radiation and coating film, which may prevent other target materials from pollution. The flange plate 4 connected with target table is equipped with three stepping motors 1 and relevant mechanical parts (not shown), which respectively rakes charge of movement of target table (lifting and falling), switch (revolution) of target position and autorotation of target. The target table, transmission mechanism and flange plate are connected with metal corrugated pipe 35 by rotation axis.

The heater 20 used in substrate heating table 30 is a kind of spiral structure of double winding resistance wire by armored thermal shield cover 28 outside. The double wound armored resistance wire is a type of nichrome. The maximum heating temperature of substrate table 30 may reach 800 C. Thermal shield cover 28 is weld by double-layer, non-magnetic stainless steel cylinder (spacing: 3 mm). The double-wound structure of heating wire makes the current direction of near resistance wire adverse (as shown in the arrows), which may further eliminate the influence of the magnetic field generated from the current. The table of substrate table 30 may be driven by stepping motor 17 to achieve even coating film effect. A thermocouple is set besides the substrate table 30 (not shown) to measure temperature. The temperature may be controlled by a temperature controller (not shown) controlling input power of heater 10.

Superconducting magnet 7 applies non-liquid helium and electrical refrigeration superconducting magnet with short-length cavity and large caliber. The maximum magnetic field strength is 10 Tesla, the uniformity is ±0.1% (1 cm DSV) and ±4% (φ5 cm×10 cm cylinder), the diameter of bore hole (room temperature aperture) is φ200 mm and the chamber length is 703 mm; the pulsed laser 20 is KrF excimer pulsed laser with 248 nm wavelength. The maximum pulse energy is 400 mJ, the average power is 6 W, the maximum frequency is 20 Hz and the pulse width is 20 ns.

Considering that the magnetic materials may influence magnetic field uniformity, and even damage certain parts or disturb the normal work of electronic control system under the magnetization and force of high magnetic field, the materials of PLD cylindrical vacuum chamber and internal and external connectors apply non-magnetic or weak-magnetic materials. For example, double-layer clip-sheath cylindrical chamber with water cooling 5, and main parts of flange plate 13 and 4 are composed of high-quality 304 stainless steel; target table 6 component is made of 316LN stainless steel; heating table 30 is made of high-purity oxygen-free copper; and the distance from driving motor and magnetic fluid sealing mechanism, etc. to superconducting magnet port is kept above 500 mm.

Double-layer clip-sheath cylindrical chamber 5 is connected to water cooling circulating system from water inlet 33 and water outlet 2. The chamber is cooled to guarantee the temperature set within superconducting magnet bore hole under normal working scope. Simultaneously, the substrate heating table 30 is set and heated at a required temperature. Video system and collimation laser 19 are opened. The collimation laser is adjusted to be coaxial with pulsed laser in advance and then focusing lens 23 and laser leading-in chamber 27 are adjusted to align collimation laser at target material 32. At this time, excimer pulsed laser 20 for coating film is opened. Pulsed laser enters into sealed laser leading-in chamber 27 installed on flange plate 13 through focusing lens 23, and enters into target material via incoming-light quartz glass window 24, 65° anti-intense laser mirror 29 and emergent-light quartz glass window 31 for PLD thin film growth. During the process of thin-film growth, magnetic field is applied through excitation source of superconducting magnet in advance to achieve in-situ growth of high magnetic field assisted PLD thin-film. Magnetic field for thin-film post-annealing treatment after thin film finishes growth may be applied.

Collimation laser 19 may be set in position 21 vertical to laser light path of pulsed laser 20. At this time, the laser emitted by collimation laser 21 completely coincides with the laser emitted by pulsed laser 20 after reflection by 45° mirror 18.

### Specific Embodiment

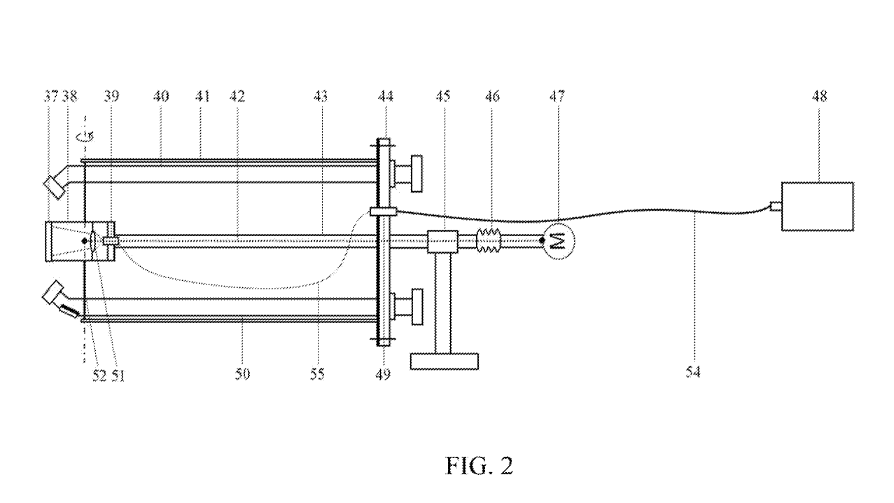

In order to change the angle between magnetic field and heating table (substrate surface of growth thin film), achieve film growth and post-annealing treatment under different magnetic fields orientation, so that thin-film growth microstructure and physical property can be regulated and controlled by magnetic field, it is necessary to design a flexible heating device. FIG. 2 gives the design plan of laser heating table. Change the flange plate 13 with substrate heating table and rotating mechanism as shown in FIG. 1 to flange plate 44 with laser heating table 38 in FIG. 2. It may achieve high magnetic field direction and higher temperature. Sealed laser leading-in chamber 50 and vacuum-sealed video-unit leading-in chamber 40 are installed on flange plate 44 in FIG. 2 are the same as relevant part 27 and 11 in FIG. 1. Similar to the assembly structure of flange plate 13 in FIG. 1, using the holder and sliding block 45, the flange plate 44 is installed on guide rail and slides, in order to facilitate assembling to double-layer clip-sheath cylindrical chamber 5 in FIG. 1. Working principle of laser heating table 38 includes the following principle: the infrared high intense laser emitted by high power infrared laser 48 will enter into fiver 54 for transmission with metal sheath from fiber coupling interface. The transmission fiber is connected to high temperature resistance fiber 55 in vacuum chamber using vacuum seal joint 49. Finally, the infrared high intense laser is output from fiver port 39 and converged on heating table 37 via a focusing lens 51 to form a facula (φ20 mm) and heat the substrate. Fiber 54 and 55 may use the same optical fiber. Fiber 55 applies bare fiber without metal sheath, which may resist high temperature and easy to realize vacuum seal. Laser heating table 38 may rotate around rotation axis 52. Rotating angle may be controlled via transfer bar 42 and stepping motor 47. Transfer motion of transfer bar 42 and stepping motor 47 may be achieved through metal elbows 46 connecting rotation axis. Laser heating table 38 is a sealed cylindrical structure, which may prevent the coating film from polluting focusing lens 51 and fiber port 39. Laser heating table 38 is connected and fixed with holder 41 installed on flange plate 44 through rotation axis 52. Thermocouple (not shown) on laser heating table 38 is used to measure and control temperature. Temperature-measuring signal may control the output power of high power infrared laser 48, using a temperature controller in order to control the temperature. The high power infrared laser 48 is solid laser with 808 nm wavelength and 100 W output power. The maximum heating temperature of laser heating table may reach 1000° C.

### Specific Embodiment III

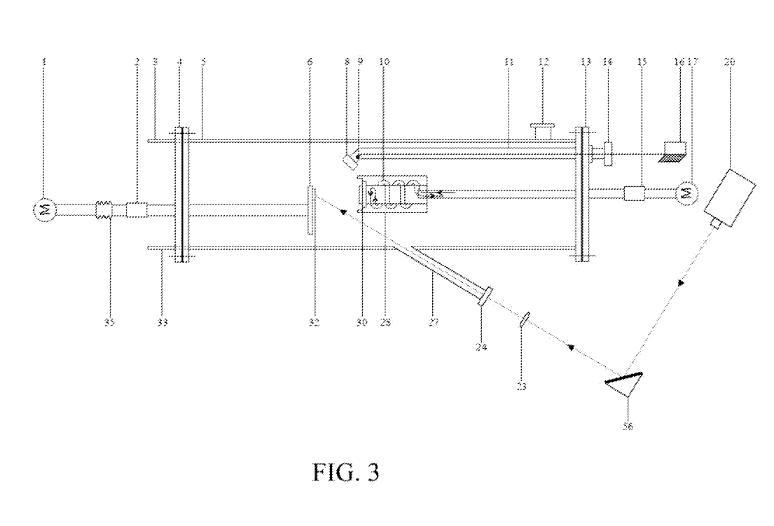

If the superconducting magnet has a small bore hole (or distance between magnetic field enter and port) and a large aperture, the PLD cylindrical vacuum chamber may be designed as the structure in FIG. 3. Differently from FIG. 1, an inclined laser leading-in chamber 27 is installed on the side pore of double-layer clip-sheath cylindrical chamber 5 rather than installing sealed laser leading-in chamber 27 on flange plate 13. A vacuum-sealed incoming-light quartz glass window 24 is installed on laser leading-in chamber 27. The laser leading-in chamber 27 is designed in an inclined angle to prevent the pulsed laser in target material 32 from blocking by the substrate heating table. The inclined angle (angle between the laser leading-in chamber 27 and chamber surface of double-layer clip sheath cylindrical chamber 5) is 30°-50°. When the system is working, a part of double-layer clip sheath cylindrical chamber 5 is placed into bore hole of superconducting magnet 7. The inclined laser leading-in chamber 27 is exposed outside magnet bore hole. The pulsed laser emitted by pulsed laser 20 will enter into inclined laser leading-in chamber 27 installed on double-layer clip-sheath cylindrical chamber 5 after reflecting by 45° mirror 56 and converging through focusing lens 23. Finally, the pulsed laser will radiate the target material for thin-film deposition and growth.

The scope of the claims should not be limited by the preferred embodiments and examples, but should be given the broadest interpretation consistent with the written description as a whole.

1. (canceled)

2. (canceled)

3. (canceled)

4. (canceled)

5. (canceled)

6. (canceled)

7. (canceled)

8. (canceled)

9. (canceled)

10. (canceled)

11. A high magnetic field assisted pulsed laser deposition system comprising:
a) a pulsed laser;
b) a pulsed laser deposition cylindrical vacuum chamber including a double-layer clip-sheath cylindrical chamber located in a bore hole of a superconducting magnet, the double-layer clip sheath having a water cooling function;
c) the double-layer clip-sheath cylindrical chamber including a flange plate, the flange plate in one side being equipped with a substrate heating table or a laser heating table and a rotating mechanism and a flange plate in another side being equipped with target components and a moving/rotating mechanism;
d) a substrate heating table and laser heating table being located in the center of the superconducting magnet;
e) a sealed laser leading-in chamber and a vacuum sealed video-unit leading-in chamber being installed on the flange plate in one side of the double-layer-clip sheath cylindrical chamber;
f) the sealed laser leading-in chamber being composed of an incoming-light quartz glass window, an emergent-light quartz glass window and an anti-intense laser mirror;
g) a pulse laser deposition cylindrical vacuum being placed horizontally and being fixed on sliding blocks using three groups of holders; wherein the first and second sliding block are installed on a Group I guide rail; a third sliding block being installed on a Group 2 guide rail; the Group I and Group Il guide rails being fixed to an optical table; and
h) the laser emitted by the pulsed laser aligning with the incoming-light quartz glass window.

12. The high magnetic field assisted pulsed laser deposition system of claim 11, wherein the laser leading-in chamber is installed on the flange plate on one side through a vacuum seal ring, which is capable of moving forwards, backwards, rotating and adjusting on the flange plate of one side, and a focusing lens installed near to an incoming-light quartz glass window, the window is located inside or outside of the laser leading-in chamber, and the reflection angle of the anti-intense laser mirror is between 45°-65°.

13. The high magnetic field assisted pulsed laser deposition system of claim 11, wherein the inner end of the vacuum-sealed video-unit leading-in-chamber is equipped with a quartz glass window and an optical camera device is capable of extending into the video-unit leading-in chamber and aligning with target components from the entrance of the video-unit leading-in chamber.

14. The high magnetic field assisted pulsed laser deposition system of claim 11, wherein a collimation laser is installed in the laser light path, the laser emitted by the pulsed laser is coaxial to the laser emitted by the collimation laser, or the laser emitted by the collimation laser is vertical to the laser emitted by the pulsed laser, and the laser emitted by the pulsed laser after reflecting with a 45° mirror is coincident to the laser emitted by the collimation laser and the collimation laser uses several milliwatt low-power and continuous visible lasers.

15. The high magnetic field assisted pulsed laser deposition system of claim 11, wherein the target components include a target table with several target positions, each target position being equipped with target materials and the target table is connected to a moving/rotating mechanism inclusive of three stepping motors; and the stepping motor is connected to target table through a metal corrugated pipe.

16. The high magnetic field assisted pulsed laser deposition system of claim 11, wherein the substrate heating table is equipped with heater including a spiral stricture wound by armored resistance wire; and the outer surface of spiral structure being covered with heat shield; and the rotating mechanism of substrate heating table contains a stepping mirror.

17. The high magnetic field assisted pulsed laser deposition system of claim 11, wherein the laser heating table is equipped with a laser heating device including an infrared superpower laser, fiber with metal sheath, vacuum sealed joints fixed in a flange plate in one side and high temperature resistance fiber within a double-layer clip-sheath cylindrical chamber connected in turn, and the fiber port of high temperature resistance fiber aligning with the heating table through a focusing lens.

18. The high magnetic field assisted pulsed laser deposition system of claim 17, wherein the laser heating table uses a sealed and cylindrical structure, the rotating mechanism of laser heating table contains stepping motor which is connected to laser heating table through a metal corrugated pipe and a transfer bar and the laser heating table is installed on the spindle.

19. The high magnetic field assisted pulsed laser deposition system of claim 11, wherein the room temperature aperture of a superconducting magnet is larger than or equal to 100 mm, the maximum magnetic field strength is larger than or equal to 3 Tesla, and the PLD cylindrical vacuum chamber and materials of internal and external connectors apply non-magnetic or weak magnetic materials.

20. The high magnetic field assisted pulsed laser deposition system of claim 19, wherein the non-magnetic or weak-magnetic materials contain high-quality 304 stainless steel, 316LN stainless steel, high-purity oxygen-free cooper and aluminum alloy materials.
